(19) United States
(12) Patent Application Publication
(10) Pub. No.: US 2023/0095607 A1
(43) Pub. Date: Mar. 30, 2023

(54) HEAT EXCHANGE DEVICE AND SINGLE CRYSTAL FURNACE

(71) Applicant: LONGI GREEN ENERGY TECHNOLGOY CO., LTD., Xi'an (CN)

(72) Inventors: Biao DING, Xi'an (CN); Hao DENG, Xi'an (CN); Shaolin MA, Xi'an (CN); Zehua FU, Xi'an (CN); Bao MA, Xi'an (CN); Jianbo WANG, Xi'an (CN)

(21) Appl. No.: 18/073,898

(22) Filed: Dec. 2, 2022

Related U.S. Application Data
(63) Continuation of application No. PCT/CN2020/133942, filed on Dec. 4, 2020.

(30) Foreign Application Priority Data
Jun. 5, 2020 (CN) 202010508184.8

(51) Int. Cl. C30B 15/14; F28D 15/00; C30B 15/22

(52) U.S. Cl. CPC C30B 15/14; C30B 15/22; F28D 15/00

(57) ABSTRACT

A heat exchanging device includes: an inner wall and an outer wall, wherein the inner wall is close to the center axis of the heat exchanging device. The inner wall and the outer wall together form a chamber for a cooling medium to flow. The inner wall is provided with at least one protrusion component having an internal cavity. The protruding direction of the protrusion component faces the center axis. The internal cavity of the protrusion component is in communication with the chamber formed by the inner wall and the outer wall. The protruding direction of the protrusion component faces the crystal bar, and the internal cavity of the protrusion component is in communication with the chamber formed by the inner wall and the outer wall, which increases the heat exchanging area, and reduces the horizontal distance between the cooling medium and the crystal bar.

The present application claims the priority of the Chinese patent application filed on Jun. 05^{th}, 2020 before the Chinese Patent Office with the application number of 202010508184.8 and the title of “HEAT EXCHANGE DEVICE AND SINGLE CRYSTAL FURNACE”, which is incorporated herein in its entirety by reference.

### TECHNICAL FIELD

The present disclosure relates to the technical field of monocrystalline silicon preparation, and particularly relates to a heat exchanging device and a single-crystal furnace.

### BACKGROUND

Currently, the main method for producing monocrystalline silicon is the czochralski method, in which, in the pulling process, the monocrystalline-silicon rod grows upwardly and vertically from the molten-silicon liquid level.

During the growth of the monocrystalline-silicon rod, it is required to absorb the crystallization latent heat dissipated by the monocrystalline-silicon rod in time, so as to provide a higher vertical temperature gradient for the growth of the monocrystalline-silicon rod, thereby ensuring that the monocrystalline-silicon rod has a high growth speed.

In the prior art, a heat shield surrounding the monocrystalline-silicon rod is provided over the crystal growth interface, and a working gas enters a pulling channel of the monocrystalline-silicon rod from the inner side of the heat shield, and purges the interface. However, such a mode has a limited effect of absorbing the heat of the monocrystalline-silicon rod, which is adverse to provide an optimized vertical temperature gradient, and restricts the further increasing of the crystal growth speed.

### SUMMARY

The present disclosure provides a heat exchanging device and a single-crystal furnace, which aims at increasing the crystal growth speed.

In the first aspect, an embodiment of the present disclosure provides a heat exchanging device, wherein the heat exchanging device includes an inner wall and an outer wall, wherein the inner wall is close to a center axis of the heat exchanging device;

the inner wall and the outer wall together form a chamber for a cooling medium to flow;

the inner wall is provided with at least one protrusion component having an internal cavity;

a protruding direction of the protrusion component faces the center axis; and

the internal cavity of the protrusion component is in communication with the chamber formed by the inner wall and the outer wall.

Optionally, a lower surface of the outer wall that is close to a bottom of a crucible is parallel to a molten-silicon liquid level.

Optionally, the inner wall includes at least one section of vertical inner wall parallel to the center axis, and the protrusion component is located on the vertical inner wall.

Optionally, the protrusion component is located on the vertical inner wall adjacent to the bottom of the crucible.

Optionally, on the condition that a quantity of the protrusion component is greater than 1, the protrusion components are distributed evenly on the inner wall.

Optionally, an included angle between the protruding direction of the protrusion component and the center axis of the heat exchanging device is greater than 0°, and less than or equal to 90°.

Optionally, the included angle between the protruding direction of the protrusion component and the center axis of the heat exchanging device is at least one of 30°, 45° and 60°.

Optionally, in a plane perpendicular to the molten-silicon liquid level, a cross section of the protrusion component is one of a parallelogram, a trapezoid, a triangle and an Ω shape; and

the protrusion component and the inner wall are integrally formed.

Optionally, in a direction from far away from a bottom of a crucible to adjacent to the bottom of the crucible, a distance between the inner wall and the center axis decreases.

Optionally, the cooling medium is at least one of water and an inert gas.

The heat exchanging device according to the embodiments of the present disclosure includes: an inner wall and an outer wall, wherein the inner wall is close to a center axis of the heat exchanging device; the inner wall and the outer wall together form a chamber for a cooling medium to flow; the inner wall is provided with at least one protrusion component having an internal cavity; and a protruding direction of the protrusion component faces the center axis. Generally, the crystal bar and the center axis of the heat exchanging device are collinear or have a very low distance. In other words, the inner wall close to the crystal bar is provided with at least one protrusion component having an internal cavity, the protruding direction of the protrusion component faces the crystal bar, the internal cavity of the protrusion component is in communication with the chamber formed by the inner wall and the outer wall. Accordingly, the cooling medium also flows through the internal cavity of the protrusion component, which increases the heat exchanging area. The protruding direction of the protrusion component faces the crystal bar, which reduces the horizontal distance between the cooling medium and the crystal bar, thereby increasing the vertical temperature gradient in the crystal-pulling process, increasing the crystal-pulling speed, and saving the crystal-pulling duration.

In the second aspect, an embodiment of the present disclosure further provides a single-crystal furnace, wherein the single-crystal furnace includes a crucible and the heat exchanging device according to any one of the above embodiments; and

the heat exchanging device is provided over the crucible.

Optionally, the single-crystal furnace further includes a heat shield located outside the heat exchanging device, and the center axis of the heat exchanging device coincides with a center axis of the heat shield.

The single-crystal furnace has the same or similar advantageous effects as those of the heat exchanging device, which, in order to avoid replication, is not discussed herein further.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure, the figures that are required to describe the embodiments of the present disclosure will be briefly described below. Apparently, the figures that are described below are embodiments of the present disclosure, and a person skilled in the art can obtain other figures according to these figures without paying creative work.

FIG. 1 shows a sectional view of a heat exchanging device according to an embodiment of the present disclosure;

FIG. 2 shows a partially enlarged schematic diagram of a heat exchanging device according to an embodiment of the present disclosure;

FIG. 3 shows a sectional view of another heat exchanging device according to an embodiment of the present disclosure;

FIG. 4 shows a partially enlarged schematic diagram of another heat exchanging device according to an embodiment of the present disclosure;

FIG. 5 shows a schematic diagram of the flowing of a cooling medium inside a heat exchanging device according to an embodiment of the present disclosure; and

FIG. 6 shows a schematic diagram of the included angle between the protruding direction of the protrusion component and the center axis of the heat exchanging device according to an embodiment of the present disclosure;

FIG. 7 is a schematic structural diagram of a single-crystal-furnace thermal-field device according to an embodiment of the present disclosure;

FIG. 8 is a schematic structural diagram of a single-crystal-furnace thermal-field device according to another embodiment of the present disclosure;

FIG. 9 is a schematic diagram of a cross-section of the heat collecting bodies of a single-crystal-furnace thermal-field device according to an embodiment of the present disclosure;

FIG. 10 is a schematic diagram of another cross-section of the heat collecting bodies of a single-crystal-furnace thermal-field device according to an embodiment of the present disclosure; and

FIG. 11 is a comparison diagram of the actual crystal-pulling speed, the preset crystal-pulling speed and the maximum crystal-pulling speed in a method for controlling single-crystal growth according to an embodiment of the present disclosure

### DESCRIPTION OF THE REFERENCE NUMBERS

1-the outer wall of the heat exchanging device, 2-the inner wall of the heat exchanging device, 3-the crucible, 4-the molten-silicon liquid level, 5-the crystal bar, 11-the surface of the inner wall that is close to the bottom of the crucible, 12-the protrusion component, 13-the inlet of the cooling medium, 14-the outlet of the cooling medium, 1010-heat shield, 1020: heat exchanging device, 1010A: horizontal face, 1030: heat collecting bodies, 1011: first surface, 1012: second surface, 1041: cooling-medium inputting pipeline, 1042: cooling-medium outputting pipeline, 2000: crucible, 2010: molten-silicon liquid level, 3010: maximum crystal-pulling speed, 3020: preset crystal-pulling speed, and 3030: actual crystal-pulling speed.

### DETAILED DESCRIPTION

The technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

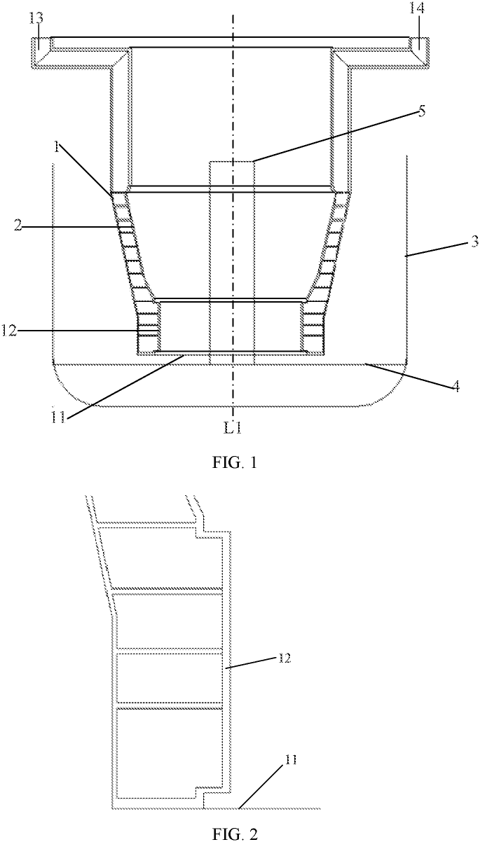

FIG. 1 shows a sectional view of a heat exchanging device according to an embodiment of the present disclosure. FIG. 2 shows a partially enlarged schematic diagram of a heat exchanging device according to an embodiment of the present disclosure. Referring to FIG. 1 and FIG. 2, an embodiment of the present disclosure provides a heat exchanging device, wherein the heat exchanging device includes an outer wall 1 and an inner wall 2, the inner wall 2 and the outer wall 1 face each other, and the inner wall 2 and the outer wall 1 together form a chamber for a cooling medium to flow.

The inner wall 2 close to the center axis L1 of the heat exchanging device is provided with at least one protrusion component 12 having an internal cavity. Generally, the crystal bar 5 and the center axis L1 of the heat exchanging device are collinear or have a very short distance. In other words, the inner wall close to the crystal bar 5 is provided with at least one protrusion component 12 having an internal cavity. The quantity of the protrusion component 12 is not particularly limited. The protruding direction of the protrusion component 12 faces the center axis L1 of the heat exchanging device; in other words, the protruding direction of the protrusion component 12 faces the crystal bar 5. The internal cavity of the protrusion component 12 is in communication with the chamber formed by the inner wall 1 and the outer wall 2. Accordingly, the cooling medium also flows through the internal cavity of the protrusion component 12, which increases the heat exchanging area. The protruding direction of the protrusion component 12 faces the crystal bar 5, which reduces the horizontal distance between the cooling medium and the crystal bar 5, thereby increasing the vertical temperature gradient in the crystal-pulling process, increasing the crystal-pulling speed, and saving the crystal-pulling duration.

For example, referring to FIG. 1, the inner wall 2 close to the center axis L1 of the heat exchanging device may include a first inner wall, a second inner wall and a third inner wall that are arranged from top to bottom in the height direction of the heat exchanging device. The first inner wall is located at the end of the heat exchanging device that is furthest from the molten-silicon liquid level 4, the third inner wall is located at the end of the heat exchanging device that is closest to the molten-silicon liquid level 4, and the distance between the third inner wall and the molten-silicon liquid level 4 may be 40 mm -60 mm. The second inner wall is located between the first inner wall and the third inner wall. All of the first inner wall, the second inner wall and the third inner wall may be provided with the protrusion component having a chamber, and the protruding direction of the protrusion component faces the center axis L1. Alternatively, the protrusion component is provided on at least one of the first inner wall, the second inner wall and the third inner wall, to increase the contact area between the cooling medium and the heat exchanging device, thereby increasing the vertical temperature gradient of the crystal growth, and increasing the crystal growth speed.

In practical applications, the surface of the end that is between the inner wall and the outer wall and is further from the bottom of the crucible may be provided with two through holes. For example, referring to FIG. 1, the upper surface of the end that is between the inner wall 2 and the outer wall 1 and is further from the bottom of the crucible 3 is provided with an inlet of the cooling medium and an outlet of the cooling medium, for example, 13 and 14. The cooling medium flows from the inlet into the chamber formed together by the inner wall 2 and the outer wall 1, and flows out of the chamber from the outlet, which may enable the cooling medium to circularly flow in the chamber formed together by the inner wall 2 and the outer wall 1 and the internal cavity of the protrusion component 12. The cooling medium, during the process of circularly flowing in the chamber formed together by the inner wall 2 and the outer wall 1 and the internal cavity of the protrusion component 12, brings away the heat of the molten-silicon liquid level 4 and the surface of the crystal bar 5, thereby increasing the vertical temperature gradient in the crystal-pulling process, increasing the crystal-pulling speed, and saving the crystal-pulling duration.

Optionally, a label 3 in FIG. 1 may be a crucible, and the crucible 3 may store molten silicon. The lower surface of the outer wall 1 that is close to the bottom of the crucible 3 may be the bottom surface of the heat exchanging device, as shown by a label 11 in FIG. 1. The lower surface 11 of the outer wall 1 that is close to the bottom of the crucible 3 is parallel to the molten-silicon liquid level 4. Accordingly, the entire surface 11 of the bottom of the heat exchanging device faces the crystalline face or the molten-silicon liquid level 4, or, in other words, the area of the bottom of the heat exchanging device that has a shorter distance to the crystalline face or the molten-silicon liquid level 4 is larger, or, in other words, the cooling medium within a larger area of the heat exchanging device has a shorter distance to the crystalline face or the molten-silicon liquid level 4, whereby the heat released by the molten silicon in crystallization can be absorbed in time, thereby increasing the vertical temperature gradient in the crystal-pulling process, increasing the crystal-pulling speed, and saving the crystal-pulling duration.

Optionally, the cooling medium is at least one of water and an inert gas. A person skilled in the art may select the suitable cooling medium according to practical situations, which is not limited in the embodiments of the present disclosure.

Optionally, referring to FIG. 1, the inner wall 2 includes at least one section of vertical inner wall parallel to the center axis L1 of the heat exchanging device. As shown in FIG. 1, the inner wall provided with the protrusion component 12 of the inner wall close to the center axis L1 of the heat exchanging device is the vertical inner wall parallel to the center axis L1 of the heat exchanging device. The section quantity of the vertical inner wall is not particularly limited. Referring to FIG. 1, the protrusion component 12 is located on the vertical inner wall. In some embodiments, the protrusion component may also be located on a non-vertical inner wall, and the heat exchanging device may also be of a tubular structure having an overall constant diameter. The horizontal distance between the vertical inner wall and the crystal bar 5 is shorter, thereby increasing the vertical temperature gradient in the crystal-pulling process, increasing the crystal-pulling speed, and saving the crystal-pulling duration.

Optionally, referring to FIG. 1, the protrusion component 12 is located on the vertical inner wall adjacent to the bottom of the crucible 3. Accordingly, the distance between the protrusion component 12 and the molten-silicon liquid level 4 is shorter, and therefore the distance between the cooling medium and the crystalline face or the molten-silicon liquid level 4 is shorter, whereby the heat released by the molten silicon in crystallization can be absorbed in time, thereby increasing the vertical temperature gradient in the crystal-pulling process, increasing the crystal-pulling speed, and saving the crystal-pulling duration.

For example, referring to FIG. 1, the inner wall 2 may include a first inner wall, a second inner wall and a third inner wall that are arranged from top to bottom in the height direction of the heat exchanging device. The first inner wall is located at the end of the heat exchanging device that is furthest from the bottom of the crucible 3, and the third inner wall is located at the end of the heat exchanging device that is closest to the bottom of the crucible 3. The second inner wall is located between the first inner wall and the third inner wall. The third inner wall is a vertical inner wall parallel to the center axis L1 of the heat exchanging device, and the protrusion component 12 is located on the third inner wall closest to the bottom of the crucible 3.

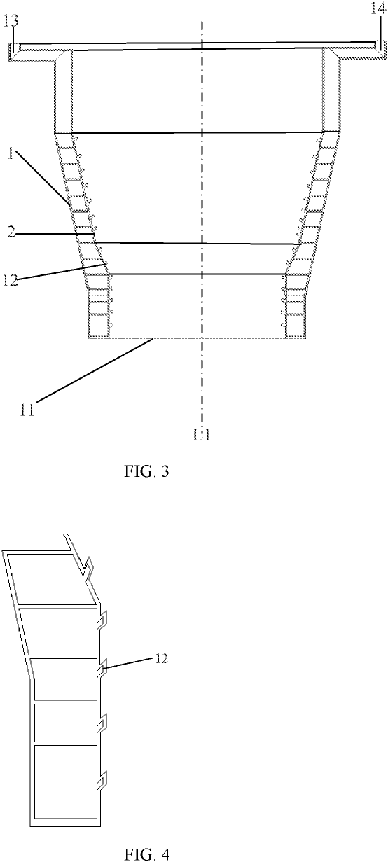

Optionally, on the condition that a quantity of the protrusion component is greater than 1, the protrusion components are distributed evenly on the inner wall. Accordingly, the cooling to the crystal bar has a good uniformity, which may increase the crystal-pulling speed. FIG. 3 shows a sectional view of another heat exchanging device according to an embodiment of the present disclosure. FIG. 4 shows a partially enlarged schematic diagram of another heat exchanging device according to an embodiment of the present disclosure. For example, referring to FIG. 3 and FIG. 4, the quantity of the protrusion component 12 is greater than 1, and the protrusion components 12 are distributed evenly on the inner wall.

It should be noted that, when the quantity of the protrusion component is greater than 1, the spacing between the protrusion components is less than 15 mm. A person skilled in the art may select the suitable spacing according to practical situations, which is not limited in the embodiments of the present disclosure.

Optionally, the protrusion component and the inner wall are integrally formed, to facilitate the manufacturing. For example, modes such as die pressing may be used. That is not particularly limited in the embodiments of the present disclosure.

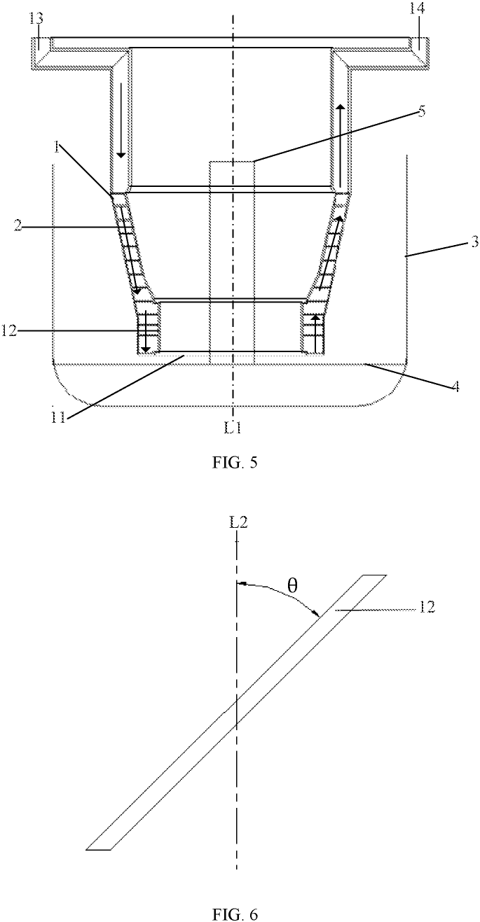

As shown in FIG. 3, the dotted line L1 is the center axis of the heat exchanging device. Optionally, the included angle between the protruding direction of the protrusion component 12 and the center axis of the heat exchanging device is greater than 0°, and less than or equal to 90°. FIG. 5 shows a schematic diagram of the flowing of a cooling medium inside a heat exchanging device according to an embodiment of the present disclosure. In FIG. 5, a label 13 may be the inlet of the cooling medium, and a label 14 may be the outlet of the cooling medium. The arrow line in FIG. 5 shows a schematic diagram of the flowing of the cooling medium inside the heat exchanging device according to an embodiment of the present disclosure. Referring to FIG. 5, the included angle between the protruding direction of the protrusion component 12 and the center axis of the heat exchanging device is within the above-described angle range, whereby the flowing direction of the cooling medium descends spirally in the direction of the arrangement of the protrusion components of the heat exchanging device, which increases the duration of the staying of the cooling medium at the crystal bar, at the crystallization interface and over the crystalline face, and can sufficiently absorb the heat of the crystal bar 5 and the crystalline face or the molten-silicon liquid level 4, to bring away more crystallization latent heat, thereby increasing the vertical temperature gradient in the crystal-pulling process, increasing the crystal-pulling speed, and saving the crystal-pulling duration. Moreover, the included angle between the protruding direction of the protrusion component 12 and the center axis of the heat exchanging device is within the above-described angle range, whereby the protrusion component 12 is easy to manufacture.

As shown in FIG. 1 or FIG. 2, the included angle between the protruding direction of the protrusion component 12 and the center axis of the heat exchanging device is 90°. Referring to FIG. 6, FIG. 6 shows a schematic diagram of the included angle between the protruding direction of the protrusion component and the center axis of the heat exchanging device according to an embodiment of the present disclosure. FIG. 6 may be a schematic diagram of the included angle between the protruding direction of the protrusion component 12 shown in FIG. 3 or FIG. 4 and the center axis of the heat exchanging device. In FIG. 6, L2 may be a dotted line parallel to the center axis of the heat exchanging device, and the value range of the included angle θ between the protruding direction of the protrusion component 12 and the center axis of the heat exchanging device is greater than 0°, and less than or equal to 90°.

Optionally, the included angle between the protruding direction of the protrusion component 12 and the center axis of the heat exchanging device is at least one of 30°, 45° and 60°. When the included angle between the protruding direction of the protrusion component 12 and the center axis of the heat exchanging device is 30°, 45° or 60°, in an aspect, as compared with other angles, the requirements on the machining precision are more easily satisfied. In another aspect, the resistance to the changing of the flowing direction of the cooling medium is small, whereby the rotary descending of the cooling medium is easily satisfied, and at the same time more crystallization latent heat is brought away.

It should be noted that, when the included angle between the protruding direction of the protrusion component 12 and the center axis of the heat exchanging device is 45°, the processing technic is simpler, and the resistance to the changing of the flowing direction of the cooling medium is smaller, whereby the rotary descending of the cooling medium is easily satisfied, and at the same time more crystallization latent heat is brought away.

Optionally, the shape of the heat exchanging device may be any one of a cylinder, a cone and a circular arc or a combination thereof. The whole of the inner wall of the heat exchanging device that is close to the center axis of the heat exchanging device may be a vertical inner wall, whereby the horizontal distance from the whole of the vertical inner wall that is on one side close to the center axis of the heat exchanging device and is perpendicular to the molten-silicon liquid level to the crystal bar is shorter, thereby increasing the vertical temperature gradient in the crystal-pulling process, increasing the crystal-pulling speed, and saving the crystal-pulling duration.

Optionally, when the whole of the inner wall of the heat exchanging device that is close to the center axis of the heat exchanging device is a vertical inner wall parallel to the center axis of the heat exchanging device, the protrusion component having the internal cavity is located on the whole of the vertical inner wall, or the protrusion component having the internal cavity is located on part of the area of the whole of the vertical inner wall. That is not particularly limited in the embodiments of the present disclosure.

Optionally, in a plane perpendicular to the molten-silicon liquid level, the cross section of the protrusion component is one of a parallelogram, a trapezoid, a triangle and an Ω shape. The parallelogram may include a rectangle and so on. The internal cavity of the protrusion component of the above-described shapes reduces the horizontal distance between the heat exchanging device and the crystal bar 5, whereby the heat of the crystal bar can be sufficiently absorbed, thereby increasing the vertical temperature gradient in the crystal-pulling process, increasing the crystal-pulling speed, and saving the crystal-pulling duration. It should be noted that, in a plane perpendicular to the molten-silicon liquid level, the cross section of the protrusion component may also be other regular or irregular shapes, to increase the contact duration and the contact area of the cooling medium with the internal cavity of the protrusion component or the chamber of a cylindrical structure. That is not particularly limited in the embodiments of the present disclosure.

For example, referring to FIG. 1 or FIG. 2, in a plane perpendicular to the molten-silicon liquid level, the cross section of the protrusion component is a rectangle. As another example, referring to FIG. 3 or FIG. 4, in a plane perpendicular to the molten-silicon liquid level, the cross section of the protrusion component is a parallelogram.

Optionally, the protrusion component 12 may be one large entirety or a plurality of small protrusion components that are arranged in the direction of the inner wall. That is not particularly limited in the embodiments of the present disclosure. For example, the protrusion component is a plurality of strip-shaped components that are arranged in the direction of the inner wall. Alternatively, the protrusion component may be formed by a plurality of sections that are arranged in the direction of the inner wall.

Optionally, in the direction from far away from the bottom of the crucible to adjacent to the bottom of the crucible, the distance between the inner wall and the center axis of the heat exchanging device decreases. Generally, the crystal bar and the center axis of the heat exchanging device are collinear or have a very short distance; in other words, the distance between the inner wall close to the bottom of the crucible and the crystal bar is reduced. In other words, if the distance to the molten-silicon liquid level is shorter, the distance between the inner wall and the crystal bar is shorter, whereby more heat of the crystal bar and the crystalline face or the molten-silicon liquid level may be simultaneously absorbed, thereby increasing the vertical temperature gradient in the crystal-pulling process, increasing the crystal-pulling speed, and saving the crystal-pulling duration.

An embodiment of the present disclosure further provides a single-crystal furnace. Referring to FIG. 1, the single-crystal furnace includes a crucible 3 and the heat exchanging device, the heat exchanging device is provided over the crucible. The crucible, the heat exchanging device and so on may refer to the above relevant description. The single-crystal furnace can have the same or similar advantageous effects as those of the heat exchanging device, which, in order to avoid replication, is not discussed herein further.

Optionally, the single-crystal furnace may further include a heat shield located outside the heat exchanging device, and the center axis of the heat exchanging device coincides with the center axis of the heat shield. By using the cooperation of the heat shield and the heat exchanging device, the heat of the crystal bar and the crystalline face is further absorbed, thereby increasing the vertical temperature gradient in the crystal-pulling process, increasing the crystal-pulling speed, and saving the crystal-pulling duration.

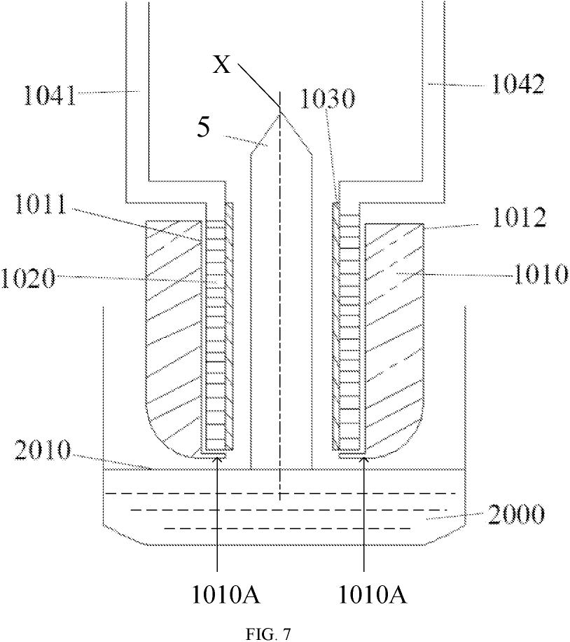

As shown in FIG. 7, the single-crystal-furnace thermal-field device according to an embodiment of the present disclosure includes:
a heat shield 1010, wherein the heat shield 1010 is provided with a gas-flow channel at the center; and
a heat exchanging device 1020, wherein the heat exchanging device 1020 is provided inside the gas-flow channel, and encloses to form a pulling channel;
the heat shield 1010 is provided over the crucible 2000; and
the heat shield 1010 has a bottom, and the bottom at least partially blocks between the heat exchanging device 1020 and a molten-silicon liquid level 2010 in the crucible 2000.

In the single-crystal-furnace thermal-field device according to the present embodiment, the heat exchanging device is provided inside the gas-flow channel formed by the heat shield, to quickly bring away the latent heat released by the crystallization, thereby, within the thermal field of the pulling channel, increasing the vertical temperature gradient of the crystal, to increase the crystal growth speed.

In the single-crystal-furnace thermal-field device according to the present embodiment, a heat insulating blanket is provided inside the heat shield, to isolate the heat from the periphery of the heat shield (for example, the molten-silicon liquid level and the thermal field outside the single-crystal furnace). When the bottom of the heat shield at least partially blocks between the heat exchanging device and the molten-silicon liquid level, the bottom of the heat shield can isolate the heat from the molten-silicon liquid level, whereby the heat exchanging device can absorb the heat around more crystal bars. In other words, by increasing the heat-insulation area of the heat shield located over the molten-silicon liquid level inside the crucible, the efficacy of the heat shield is improved, to increase the vertical temperature gradient of the crystal, and increase the crystal-pulling speed.

In another aspect, the heat shield is used to guide the gas flow formed by the protecting gas (for example, argon).

As compared with the heat shields in the prior art having merely an upright side wall, in the single-crystal-furnace thermal-field device according to the present embodiment, the bottom of the heat shield at least partially blocks between the heat exchanging device and the molten-silicon liquid level, which does not only satisfy the upward growth of the crystal passing through the bottom of the heat shield, but also increases the heat-insulation area of the heat shield located over the molten-silicon liquid level inside the crucible, thereby improving the efficacy of the heat shield, to increase the vertical temperature gradient of the crystal, and increase the crystal-pulling speed.

In order to further increase the efficacy of the heat shield, in the single-crystal-furnace thermal-field device according to the present embodiment, the bottom has a horizontal face 1010A on the side facing the molten-silicon liquid level 2010; and

the distance between the horizontal face 1010A and the molten-silicon liquid level 2010 is 10-60 mm.

In the single-crystal-furnace thermal-field device according to the present embodiment, the bottom of the heat shield is configured as a horizontal face on the side facing the molten-silicon liquid level, which can reduce the distance between the heat shield and the liquid level, whereby the heat exchanging device can be close to the growth interface, to absorb the latent heat released by the crystallization of the molten silicon to the largest extent, thereby increasing the vertical temperature gradient of the crystal, and increasing the crystal-pulling speed.

Preferably, the distance between the horizontal face 1010A and the molten-silicon liquid level 2010 is 10-60 mm.

Preferably, the distance between the horizontal face 1010A and the molten-silicon liquid level 2010 is 10 mm.

It should be understood that, if the distance between the bottom of the heat shield and the melt liquid level is lower, then the distance between the heat exchanging device provided inside the heat shield and the growth interface is lower, and if the heat exchanging device is close to the growth interface, then the heat exchanging device absorbs more heat, whereby the heat exchanging device can absorb more temperature of the growth interface, thereby increasing the vertical temperature gradient of the crystal, and finally increasing the crystal-pulling speed.

Optionally, in the single-crystal-furnace thermal-field device according to the present embodiment, the heat exchanging device 1020 is provided at the side wall of the heat shield 1010.

Optionally, the single-crystal-furnace thermal-field device according to the present embodiment further includes:
heat collecting bodies 1030;
the heat collecting bodies 1030 are provided at the heat exchanging device 1020 in groups; and
the heat collecting bodies 1030 are located on the side of the heat exchanging device 1020 that faces the pulling channel.

In the single-crystal-furnace thermal-field device according to the present embodiment, on the side of the heat exchanging device facing the pulling channel, the heat collecting bodies are provided in groups, thereby collecting more heat from the pulling channel, and the heat exchanging device guides the heat out of the single-crystal furnace, to increase the vertical temperature gradient of the crystal, and increase the crystal-pulling speed.

Optionally, in the single-crystal-furnace thermal-field device according to the present embodiment;
each of the heat collecting bodies 1030 includes a protrusion; and
the protrusion protrudes in the direction from the heat exchanging device 1020 to the pulling channel.

In the single-crystal-furnace thermal-field device according to the present embodiment, the protrusion protruding in the direction facing the pulling channel further increases the contact area with the thermal field, thereby collecting more heat from the pulling channel, and the heat exchanging device guides the heat out of the single-crystal furnace, to increase the vertical temperature gradient of the crystal, and increase the crystal-pulling speed.

The protrusion may be separate protrusions, and may be a trigonal prism, a polygonal prism or a warped fin. In this case, a plurality of separate protrusions are dispersedly provided on the side of the heat exchanging device 1020 facing the pulling channel.

Preferably, the extension trajectory of the protrusions of each of the groups of the heat collecting bodies may extend in the direction of the center axis X of the heat shield 1010, or extend in the direction perpendicular to the center axis X of the heat shield 1010.

When the protrusion is of a continuously extending columnar shape, its cross-section may be any one of a triangle, a trapezoid and a rectangle. Partially sectional expanded views of a plurality of groups of the columnar-shaped protrusions that are parallel are shown in FIG. 9 or FIG. 10.

It should be understood that, in practical usage, the cross-sectional shape of the protruding surface of the heat collecting bodies may also be other shapes that can be continuously arranged and whose arrangement structure can increase the heat exchanging surface area, such as a rectangle, a hemispherical shape, an Ω shape and an S shape.

It should be understood that, in practical usage, the protrusions of the heat collecting bodies may also have a plurality of inwardly concave surfaces, thereby further increasing the heat-exchanging area of the heat collecting bodies.

Optionally, in order to reduce the difficulty in the production and the manufacturing, and in turn reduce the cost in the purchasing and the maintenance of the single-crystal furnace, in the single-crystal-furnace thermal-field device, the heat collecting bodies 1030 and the heat exchanging device 1020 are integrally formed; or
the heat collecting bodies 1030 are welded to the heat exchanging device 1020; or
the heat collecting bodies 1030 are thread-connected to the heat exchanging device 1020.

In order to further increase the surface available for the heat exchanging, to increase the heat-exchanging speed, in the single-crystal-furnace thermal-field device according to the present embodiment,
the heat exchanging device 1020 includes a first shape contour and a second shape contour that are connected from top to bottom;
the first shape contour is a hollow truncated circular-conical tube;
the second shape contour is a hollow cylindrical tube;
the first shape contour closes up from top to bottom; and
the inner diameter of the lower end of the first shape contour is equal to the inner diameter of the second shape contour.

In the single-crystal-furnace thermal-field device according to the present embodiment, overall, the upper part of the heat exchanging device is a hollow inversely placed circular truncated cone (the upper part is larger and the lower part is smaller), and the lower part is a hollow cylinder. When the heat exchanging device is considered as an annular structural member of a constant wall thickness or a varying wall thickness, the heat exchanging device is formed by a first shape contour and a second shape contour that are connected from top to bottom. The first shape contour is a hollow truncated circular-conical tube, and the second shape contour is a hollow cylindrical tube. The first shape contour closes up from top to bottom, and the inner diameter of the lower end of the first shape contour is equal to the inner diameter of the second shape contour.

In the single-crystal-furnace thermal-field device according to the present embodiment, the heat exchanging device whose shape has been optimized has more surfaces for heat exchanging, and, by quickly absorbing the heat released by the crystallization, forms a further optimized thermal field inside the pulling channel, thereby increasing the vertical temperature gradient of the crystal, and finally increasing the crystal growth speed.

Particularly, by increasing the heat exchanging surface, the amplitude of the heat absorption by the heat exchanging device is increased, and, in unit time, the heat exchanging device whose shape has been optimized can absorb more heat from the growth interface.

It should be noted that the “truncated circular cone” as used herein refers to a partial circular cone or circular-conical surface that is obtained by truncating a complete circular cone or circular-conical surface transversely from the side close to its vertex, wherein the dimension of one of it ends is greater than the dimension of the other end (for example, the upper part is larger and the lower part is smaller) or the dimension of one of it ends is less than the dimension of the other end (for example, the upper part is smaller and the lower part is larger).

Regarding the “hollow truncated conic tube” as used herein, its outer contour is a truncated circular cone, and its inner contour is also a truncated circular cone. If, in its axially extending direction, the distances between its outer contour and its inner contour are equal at all positions, it is of a constant wall thickness. If, in its axially extending direction, the distances between its outer contour and its inner contour vary at the positions, it is of a varying wall thickness.

It should be noted that the above description describes the inner and outer contours of the heat exchanging device, and does not limit the particular structure or the components of the heat exchanging device or the shapes of the inner and outer surfaces, and any heat exchanging device that satisfies the above-described contours have the similar technical effect.

As containing piece and contained piece, in order to improve the effect of the gas-flow guiding by the heat shield, the surface contour of the fourth inner wall of the heat shield 1010 and the shape contour of the heat exchanging device 1020 match. Correspondingly, in the single-crystal-furnace thermal-field device according to the present embodiment,
the heat shield 1010 includes a fourth inner wall 1011;
the fourth inner wall 1011 includes a second inner-wall contour and a third inner-wall contour that are connected from top to bottom;
the second inner-wall contour is a truncated circular cone;
the third inner-wall contour is a cylinder;
the second inner-wall contour closes up from top to bottom; and
the inner diameter of the lower end of the second inner-wall contour is equal to the inner diameter of the third inner-wall contour.

In the single-crystal-furnace thermal-field device according to the present embodiment, overall, the upper part of the fourth inner wall of the heat shield defines a truncated circular-conical space (the upper part is larger and the lower part is smaller), and the lower part of the fourth inner wall of the heat shield defines a cylindrical space. Particularly, the fourth inner wall 1011 of the heat shield has a surface contour, and the surface contour is formed by a second inner-wall contour and a third inner-wall contour that are connected from top to bottom. The second inner-wall contour is a truncated circular-conical face (or an inversely placed circular truncated conical face), and the third inner-wall contour is a cylindrical face. The second inner-wall contour closes up from top to bottom, and the inner diameter of the lower end of the second inner-wall contour is equal to the inner diameter of the third inner-wall contour.

In the single-crystal-furnace thermal-field device according to the present embodiment, as the shape of the fourth inner wall has been optimized, the heat shield has more surface for heat insulation, so as to form a further optimized thermal field inside the pulling channel, thereby increasing the vertical temperature gradient of the crystal, and finally increasing the crystal growth speed.

It should be noted that the “truncated circular cone” as used herein refers to a partial circular cone or circular-conical surface that is obtained by truncating a complete circular cone or circular-conical surface transversely from the side close to its vertex, wherein the dimension of one of it ends is greater than the dimension of the other end (for example, the upper part is larger and the lower part is smaller) or the dimension of one of it ends is less than the dimension of the other end (for example, the upper part is smaller and the lower part is larger).

It should be noted that the above description describes the surface contour of the fourth inner wall of the heat shield, and does not limit the particular structure or components or shape of the fourth inner wall of the heat shield, and any fourth inner wall of the heat shield that satisfies the above-described surface contour has the similar technical effect.

In order to further optimize the thermal field inside the pulling channel, in the single-crystal-furnace thermal-field device according to the present embodiment;

the fourth inner wall 1011 further includes a first inner-wall contour that is connected over the second inner-wall contour;
the first inner-wall contour is a cylinder; and
the inner diameter of the upper end of the second inner-wall contour is equal to the inner diameter of the first inner-wall contour.

In the single-crystal-furnace thermal-field device according to the present embodiment, overall, the uppermost part of the fourth inner wall of the heat shield defines a cylindrical space. Particularly, the fourth inner wall 1011 of the heat shield has a surface contour, and the surface contour is formed by a first inner-wall contour, a second inner-wall contour and a third inner-wall contour that are connected from top to bottom. The first inner-wall contour is a cylindrical face, the second inner-wall contour is a truncated circular-conical face (or an inversely placed circular truncated conical face), and the third inner-wall contour is a cylindrical face. The second inner-wall contour closes up from top to bottom, and the lower end of the second inner-wall contour has the equal dimension to that of the third inner-wall contour. The inner diameter of the upper end of the second inner-wall contour is equal to the inner diameter of the first inner-wall contour.

In the single-crystal-furnace thermal-field device according to the present embodiment, the fourth inner wall is of a three-sectional shape, the heat shield whose shape has been optimized forms a further optimized thermal field inside the pulling channel, thereby increasing the vertical temperature gradient of the crystal, and finally increasing the crystal growth speed.

It should be noted that the “truncated circular cone” as used herein refers to a partial circular cone or circular-conical surface that is obtained by truncating a complete circular cone or circular-conical surface transversely from the side close to its vertex, wherein the dimension of one of it ends is greater than the dimension of the other end (for example, the upper part is larger and the lower part is smaller) or the dimension of one of it ends is less than the dimension of the other end (for example, the upper part is smaller and the lower part is larger).

It should be noted that the above description describes the surface contour of the fourth inner wall of the heat shield, and does not limit the particular structure or components or shape of the fourth inner wall of the heat shield, and any fourth inner wall of the heat shield that satisfies the above-described surface contour has the similar technical effect.

Particularly, in the direction of the center axis of the heat shield 1010, the lateral distance between the fourth inner wall of a lowest distance from the heat exchanging device inside the heat shield 1010 and the outer wall of the heat exchanging device 1020 maintains substantially constant, whereby the gas-flow resistance inside the gas-flow channel is reduced, and the flow field of the gas flow is more stable.

Optionally, the single-crystal-furnace thermal-field device according to the present embodiment further includes:
a cooling-medium inputting pipeline 1041;
a cooling-medium outputting pipeline 1042; and
a chamber for the cooling medium to flow through is provided inside the heat exchanging device 1020;
the cooling medium flowing into the chamber of the heat exchanging device 1020 is delivered by the cooling-medium inputting pipeline 1041; and
the cooling medium flowing out of the chamber of the heat exchanging device 1020 is delivered by the cooling-medium outputting pipeline 1042.

The cooling medium inside the chamber provided inside the single-crystal-furnace thermal-field device according to the present embodiment quickly guides the latent heat released by the crystallization out of the furnace, to bring away the heat by using the cooling medium, thereby increasing the vertical temperature gradient of the crystal, and thus increasing the growth speed of the single crystal.

Optionally, in the single-crystal-furnace thermal-field device according to the present embodiment, the cooling medium is any one of liquid nitrogen, liquid argon and industrial water.

Preferably, the chamber, in its direction of extension, has a helically ascending trajectory, or an end-to-end U-shaped trajectory.

Preferably, surrounding the heat exchanging device, the chamber may have one trajectory, and may also have a plurality of trajectories that are arranged in parallel and separately.

By using a fluid storing device (for storing the cooling medium) and a liquid delivering device (for example, a fluid pump such as a gear pump and a vane pump) in the prior art, the cooling medium is circulated inside the chamber of the heat exchanging device, thereby realizing heat exchanging, to bring away the latent heat released by the crystallization of the molten silicon.

In this case, the cooling-medium inputting pipeline 1041, the cooling-medium outputting pipeline 1042, the chamber inside the heat exchanging device 1020, the liquid delivering device (for example, a fluid pump such as a gear pump and a vane pump) and the fluid storing device (for storing the cooling medium, such as a liquid storing tank) and other components (for example, a fluid-pressure regulating device and a fluid-flow-rate regulating device) together form a circulating and cooling system.

It should be understood that the flow rate of the cooling medium inside the liquid chamber may be adjusted (for example, increasing or reducing the volume flow rate of the cooling medium) to further adjust the vertical temperature gradient.

The thermal-field device that can increase the temperature gradient is disposed over the crucible 2000, to obtain the reformed single-crystal furnace. The single-crystal furnace can also increase the vertical temperature gradient in the crystal growth direction, to increase the crystal-pulling speed.

As shown in FIG. 7, in the single-crystal-furnace thermal-field device according to an embodiment of the present disclosure, the heat shield 1010 is provided over the crucible, and the heat shield 1010 includes a first surface 1011 close to the crystal bar 5 and a second surface 1012 opposite to the first surface 1011. The first surface 1011 closes around its central axis, to form a gas-flow channel. The second surface 1012 is the outer wall of the heat shield. A heat insulating material, for example, a heat insulating blanket, is provided between the first surface 1011 and the second surface 1012.

The heat shield forms the gas-flow flowing inside the single-crystal furnace, controls the temperature gradient of the thermal field around the crystal bar 5, and isolates the crystal bar 5 from the high-temperature zone at the heater.

Preferably, the heat exchanging device 1020 is of an axially symmetric structure formed around the center axis X of the heat shield, includes an annular side wall and a hollow annular bottom, and has an L-shaped longitudinal section. Preferably, a chamber for the cooling medium to flow through is provided at its bottom.

Preferably, the contour of the heat exchanging device forms a tube whose two ends are open in the space, and the tube, in its direction of extension, is formed by one or more of a hollow truncated circular-cone-shaped tube, a hollow cylindrical tube, a hollow drum-shaped tube and a hollow polygonal tube.

As shown in FIG. 7, a plurality of groups of outwardly protruding heat collecting bodies are provided on the side of the heat exchanging device 1020 that is close to the crystal bar 5, the plurality of groups of heat collecting bodies are separately and evenly arranged, and their contact points or connecting points with the heat exchanging device 1020 are located in a circumferential surface coaxial to the crystal bar.

The protruding heat collecting bodies have a plurality of outer surfaces, which, as compared with the circular-arc contour surface of the heat exchanging device, increases the contact area between the thermal field around the crystal bar and the heat exchanging device 1020, which can increase the heat transfer efficiency, thereby further increasing the vertical temperature gradient, to increase the crystal-pulling speed.

Preferably, the cooling medium is a gas or a liquid, for example, liquid nitrogen, liquid argon and cooling water. In usage, they may be selected reasonably according to demands. Inert gases such as liquid nitrogen and liquid argon, as the cooling medium, have a high heat capacity, and can improve the safety of the production inside the closed high-heat space. The thermal-field device according to the present embodiment is cooled by using liquid argon. Liquid argon, as an inert gas, has a stable property and a low safety risk.

Preferably, the heat collecting bodies and the heat exchanging device are integrally formed. Preferably, the heat collecting bodies are arranged separately on the surface of the heat exchanging device that faces the crystal bar by means of welding, adhering and so on.

The above-described connection modes of the heat collecting bodies and the heat exchanging device facilitate manufacturing or facilitate repairment, which directly reduces the cost on the purchasing and the maintenance of the pulling device, thereby further reducing the production cost of czochralski silicon.

Preferably, both of the heat exchanging device and the heat collecting bodies are made from stainless steel, which has a good effect of heat dissipation, is incorruptible and has a long service life.

As shown in FIG. 7, the contour of the heat exchanging device 1020 is a constant-diameter hollow cylinder. In this case, the contour of the first surface 1011 of the heat shield and the contour of the heat exchanging device 1020 match, and the distance between them is approximately equal in the direction of the central axis of the crystal bar.

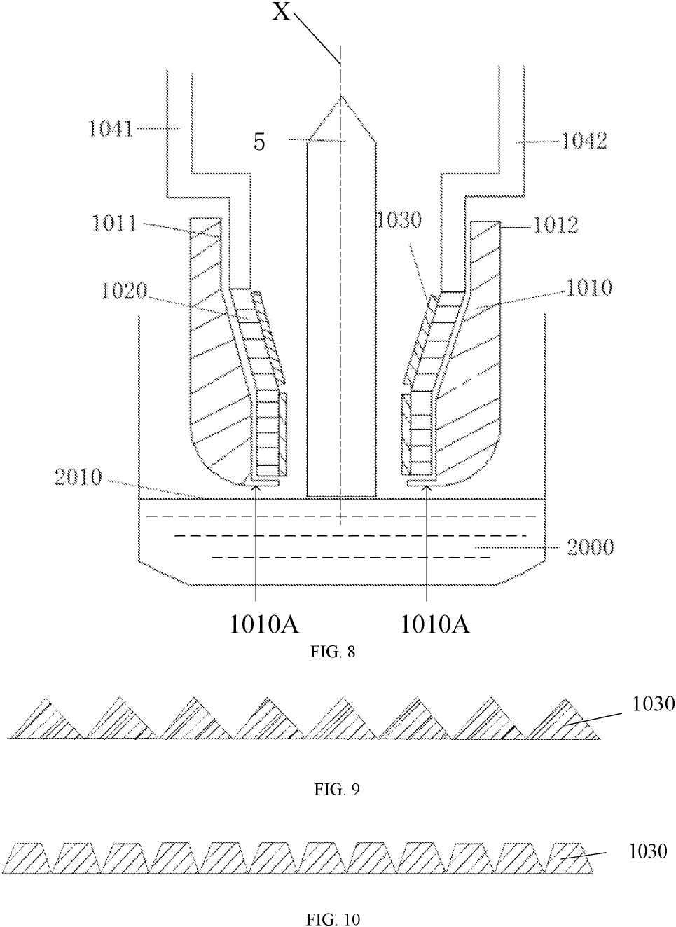

As shown in FIG. 8, the contour of the heat exchanging device 1020 is formed by connecting a downwardly closing-up truncated circular cone and a constant-diameter cylinder. In this case, the contour of the first surface 1011 of the heat shield and the contour of the heat exchanging device 1020 match, and the distance between them is approximately equal in the direction of the central axis of the crystal bar.

In this case, the surface of the heat exchanging device that is located within the thermal field has an inclining angle or an arc-shaped curve, which further increases the heat-exchanging area, and thus has a better effect of heat exchanging.

In this case, the inner surface of the side of the heat shield that faces the pulling channel has an inclining angle or an arc-shaped curve, which further increases the heat-insulation area, and thus has a better effect of heat insulation. In this case, the protruding heat collecting bodies, on the side facing the crystal bar, are arranged separately and in groups in the circumferential direction of the varying-diameter circular-conical surface and the circumferential direction of the constant-diameter cylindrical face by means of welding, adhering, forming integrally with the heat exchanging device and so on. The heat exchanging device is on the surface facing the crystal bar.

In conclusion, in the thermal-field device according to the embodiments of the present disclosure, by providing the horizontal face at the bottom of the heat shield, the bottom of the heat shield partially blocks between the heat exchanging device and the molten-silicon liquid level, to isolate the heat from the molten-silicon liquid level, whereby the heat exchanging device can absorb the heat around more crystal bars. In other words, by increasing the heat-insulation area of the heat shield located over the molten-silicon liquid level inside the crucible, the efficacy of the heat shield is improved, to increase the vertical temperature gradient of the crystal, to increase the crystal growth speed (or the crystal-pulling speed).The bottom of the heat shield has the horizontal face , whereby the lower part of the heat shield has a lower distance from the surface of the molten silicon, and can absorb more latent heat released by the crystallization of the molten silicon. By providing the heat exchanging device having the circulating and cooling chamber, and providing the heat collecting bodies on the other side where the heat exchanging device faces the heat shield, the heat-exchanging area is further increased, thereby effectively increasing the vertical temperature gradient of the crystal, and increasing the crystal-pulling speed and efficiency.

In another aspect, a method for controlling single-crystal growth that applies the above-described thermal-field device and single-crystal furnace according to an embodiment of the present disclosure includes:
step S1: at stages of single-crystal growth, acquiring a predetermined maximum crystal-pulling speed V1M;
step S2: according to a pre-stored speed-difference threshold V1T, determining a preset crystal-pulling speed V1P; and
step S3: according to the difference between an actual crystal-pulling speed that is measured at a specified first controlling moment and the preset crystal-pulling speed V1P, adjusting the heating power of the heater and/or adjusting the distance between a horizontal face of the bottom of the heat shield and the molten-silicon liquid level and/or adjusting the flow rate of the cooling medium inside the chamber of the heat exchanging device, so that an actual crystal-pulling speed that is measured at a specified second controlling moment matches with the preset crystal-pulling speed V1P;

wherein the stages of single-crystal growth are sequentially a seeding stage, a shouldering stage and a shoulder-circuiting stage.

In the method according to the present embodiment, the specified first controlling moment is before the specified second controlling moment.

In the method according to the present embodiment, the predetermined maximum crystal-pulling speed V1M may be acquired from a controlling-parameter setting interface displayed in a display screen of the single-crystal furnace.

In the method according to the present embodiment, the predetermined maximum crystal-pulling speed V1M is determined by calculating according to the crystal-pulling speeds in the single-crystal growth stages when the crystal deforms or distorts.

It should be noted that the preset crystal-pulling speed in the step S2 is not greater than the maximum crystal-pulling speed V1M, and the difference between the preset crystal-pulling speed V1P and the maximum crystal-pulling speed V1M is not less than the predetermined and pre-stored speed-difference threshold V1T.

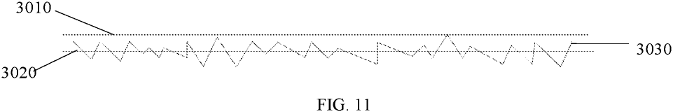

FIG. 11 shows the relative magnitude relation between the maximum crystal-pulling speed 3010, the preset crystal-pulling speed 3020 and the actual crystal-pulling speed 3030. It can be known from FIG. 11 that the preset crystal-pulling speed is less than the maximum crystal-pulling speed, and the actual crystal-pulling speed fluctuates around the preset crystal-pulling speed.

Preferably, the maximum crystal-pulling speed of the single-crystal furnace applying the above-described thermal-field device is 150 mm/h, and the preset crystal-pulling speed is set to be 145 mm/h.

Because the temperature inside the single-crystal furnace continuously changes, the actual crystal-pulling speed in the step S3 also continuously changes.

The method for controlling single-crystal growth that applies the above-described thermal-field device and single-crystal furnace according to an embodiment of the present disclosure is applied to the above-described thermal-field device and single-crystal furnace, changes the temperature and the thermal field inside the single-crystal furnace by changing the power of the heater, and by adjusting the distance between the horizontal face of the bottom of the heat shield and the molten-silicon liquid level and/or adjusting the flow rate of the cooling medium inside the chamber of the heat exchanging device, increases the heat absorbed from the growth interface, thereby increasing the vertical temperature gradient of the single crystal, to control the actual crystal-pulling speed to fluctuate within the specified range of the preset crystal-pulling speed, to ensure the stable crystal growth while increasing the crystal-pulling speed.

Particularly, the changing the temperature and the thermal field inside the single-crystal furnace by changing the power includes, by adjusting the heating power of the heater, causing the temperature inside the thermal field of the single-crystal furnace to continuously change.

Particularly, the increasing the heat absorbed from the growth interface includes:
adjusting the distance between the horizontal face of the bottom of the heat shield and the molten-silicon liquid level; and/or
adjusting the flow rate of the cooling medium inside the chamber of the heat exchanging device.

Particularly, in the controlling-parameter setting interface displayed in the display screen of the single-crystal furnace, the numerical values of the above-described parameters are changed, whereby the power is changed and the temperature and the thermal field inside the single-crystal furnace change, or the heat absorbed from the growth interface is increased, whereby the temperature and the thermal-field distribution inside the single-crystal furnace change, to control the actual crystal-pulling speed to fluctuate within the specified range of the preset crystal-pulling speed, to ensure the stable crystal growth while increasing the crystal-pulling speed.

The method for controlling single-crystal growth according to the present disclosure is applied to the above-described thermal-field device and single-crystal furnace, changes the temperature and the thermal field inside the single-crystal furnace by changing the power, and by adjusting the distance between the horizontal face of the bottom of the heat shield and the molten-silicon liquid level and/or adjusting the flow rate of the cooling medium inside the chamber of the heat exchanging device, absorbs the latent heat released from the growth interface, thereby increasing the vertical temperature gradient of the single crystal, to control the actual crystal-pulling speed to fluctuate within the specified range of the preset crystal-pulling speed, to ensure the stable crystal growth while increasing the crystal-pulling speed.

It should be noted that the terms “include”, “comprise” or any variants thereof, as used herein, are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a ...” does not exclude additional same element in the process, method, article or device comprising the element.

The embodiments of the present disclosure are described above with reference to the drawings. However, the present disclosure is not limited to the above particular embodiments. The above particular embodiments are merely illustrative, rather than limitative. A person skilled in the art, under the motivation of the present disclosure, can make many variations without departing from the spirit of the present disclosure and the protection scope of the claims, and all of the variations fall within the protection scope of the present disclosure.

The above-described device embodiments are merely illustrative, wherein the units that are described as separate components may or may not be physically separate, and the components that are displayed as units may or may not be physical units; in other words, they may be located at the same one location, and may also be distributed to a plurality of network units. Some or all of the modules may be selected according to the actual demands to realize the purposes of the solutions of the embodiments. A person skilled in the art can understand and implement the technical solutions without paying creative work.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “comprise” does not exclude elements or steps that are not listed in the claims. The word “a” or “an” preceding an element does not exclude the existing of a plurality of such elements. The present disclosure may be implemented by means of hardware comprising several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A heat exchanging device, wherein the heat exchanging device comprises an inner wall and an outer wall, wherein the inner wall is close to a center axis of the heat exchanging device;
the inner wall and the outer wall together form a chamber for a cooling medium to flow;
the inner wall is provided with at least one protrusion component having an internal cavity;
a protruding direction of the protrusion component faces the center axis; and
the internal cavity of the protrusion component is in communication with the chamber formed by the inner wall and the outer wall.

2. The heat exchanging device according to claim 1, wherein a lower surface of the outer wall that is close to a bottom of a crucible is parallel to a molten-silicon liquid level.

3. The heat exchanging device according to claim 1, wherein the inner wall comprises at least one section of vertical inner wall parallel to the center axis, and the protrusion component is located on the vertical inner wall.

4. The heat exchanging device according to claim 3, wherein the protrusion component is located on the vertical inner wall adjacent to the bottom of the crucible.

5. The heat exchanging device according to claim 1, wherein on the condition that a quantity of the protrusion component is greater than 1, the protrusion components are distributed evenly on the inner wall.

6. The heat exchanging device according to claim 1, wherein an included angle between the protruding direction of the protrusion component and the center axis of the heat exchanging device is greater than 0°, and less than or equal to 90°.

7. The heat exchanging device according to claim 1, wherein the included angle between the protruding direction of the protrusion component and the center axis of the heat exchanging device is at least one of 30°, 45° and 60°.

8. The heat exchanging device according to claim 1, wherein in a plane perpendicular to the molten-silicon liquid level, a cross section of the protrusion component is one of a parallelogram, a trapezoid, a triangle and an Ω shape; and
the protrusion component and the inner wall are integrally formed.

9. The heat exchanging device according to claim 1, wherein in a direction from far away from a bottom of a crucible to adjacent to the bottom of the crucible, a distance between the inner wall and the center axis decreases.

10. A thermal-field device, wherein the thermal-field device comprises the heat exchanging device according to claim 1 and a heat shield located on an outer side of the heat exchanging device, and the center axis of the heat exchanging device coincides with a center axis of the heat shield.

11. The thermal-field device according to claim 10, wherein the heat shield is provided with a gas-flow channel at a center;
the heat exchanging device is provided inside the gas-flow channel, and encloses to form a pulling channel;
the heat shield is provided over a crucible; and
the heat shield has a bottom, and the bottom at least partially blocks between the heat exchanging device and a molten-silicon liquid level in the crucible.

12. The thermal-field device according to claim 11, wherein
the bottom is provided with a horizontal face on one side facing the molten-silicon liquid level; and
a distance between the horizontal face and the molten-silicon liquid level is 10-60 mm.

13. The thermal-field device according to claim 11, wherein heat collecting bodies are provided on the inner wall, and the heat collecting bodies are provided at the heat exchanging device in groups; and
the heat collecting bodies are located on one side of the heat exchanging device that faces the pulling channel.

14. The thermal-field device according to claim 13, wherein
each of the heat collecting bodies comprises a protrusion; and
the protrusion protrudes in a direction from the heat exchanging device to the pulling channel.

15. The thermal-field device according to claim 13, wherein
the heat collecting bodies and the heat exchanging device are integrally formed; or
the heat collecting bodies are welded to the heat exchanging device; or
the heat collecting bodies are thread-connected to the heat exchanging device.

16. The thermal-field device according to claim 10, wherein
the heat exchanging device comprises a first shape contour and a second shape contour that are connected from top to bottom;
the first shape contour is a hollow truncated circular-conical tube;
the second shape contour is a hollow cylindrical tube;
the first shape contour closes up from top to bottom; and
an inner diameter of a lower end of the first shape contour is equal to an inner diameter of the second shape contour.

17. The thermal-field device according to claim 10, wherein
the heat shield comprises a fourth inner wall;
the fourth inner wall comprises a second inner-wall contour and a third inner-wall contour that are connected from top to bottom;
the second inner-wall contour is a truncated circular cone;
the third inner-wall contour is a cylinder;
the second inner-wall contour closes up from top to bottom; and
an inner diameter of a lower end of the second inner-wall contour is equal to an inner diameter of the third inner-wall contour.

18. The thermal-field device according to claim 17, wherein
the fourth inner wall further comprises a first inner-wall contour that is connected over the second inner-wall contour;
the first inner-wall contour is a cylinder; and
an inner diameter of an upper end of the second inner-wall contour is equal to an inner diameter of the first inner-wall contour.

19. The thermal-field device according to claim 10, wherein the thermal-field device further comprises:
a cooling-medium inputting pipeline; and
a cooling-medium outputting pipeline;
wherein, a cooling medium flowing into the chamber of the heat exchanging device is delivered by the cooling-medium inputting pipeline; and
a cooling medium flowing out of the chamber of the heat exchanging device is delivered by the cooling-medium outputting pipeline.

20. The thermal-field device according to claim 10, wherein a protruding direction of the protrusion component faces the center axis.

21. A single-crystal furnace, wherein the single-crystal furnace comprises:
a crucible;
a heater, provided on an outer side of the crucible, to heat the crucible;
the thermal-field device according to claim 10; and
the thermal-field device is provided over the crucible.

22. A method for controlling single-crystal growth, wherein the method is applied to the single-crystal furnace according to claim 21, and comprises:
step S1: at stages of single-crystal growth, acquiring a predetermined maximum crystal-pulling speed V1M;
step S2: according to a pre-stored speed-difference threshold V1T, determining a preset crystal-pulling speed V1P; and
step S3: according to a difference between an actual crystal-pulling speed that is measured at a specified first controlling moment and the preset crystal-pulling speed V1P, adjusting a heating power of the heater and/or adjusting a distance between a horizontal face of a bottom of the heat shield and a molten-silicon liquid level and/or adjusting a flow rate of the cooling medium inside the chamber of the heat exchanging device, so that an actual crystal-pulling speed that is measured at a specified second controlling moment matches with the preset crystal-pulling speed V1P;
wherein the stages of single-crystal growth are sequentially a seeding stage, a shouldering stage and a shoulder-circuiting stage.
